(19) United States
(12) Patent Application Publication
(10) Pub. No.: US 2023/0120331 A1
(43) Pub. Date: Apr. 20, 2023

(54) VERTICALLY ALIGNED CARBON NANOTUBE BASED STRAIN SENSOR

(71) Applicant: The Hong Kong University of Science and Technology, Hong Kong (CN)

(72) Inventors: Xiaoyi WANG, Hong Kong (CN); Yang DENG, Hong Kong (CN); Hongyu YU, Hong Kong (CN)

(21) Appl. No.: 17/934,842

(22) Filed: Sep. 23, 2022

Related U.S. Application Data
(60) Provisional application No. 63/257,128, filed on Oct. 19, 2021.

(51) Int. Cl. G01B 7/16; C23C 16/26; H01L 51/00

(52) U.S. Cl. CPC G01B 7/20; C23C 16/26; H01L 51/0048

(57) ABSTRACT

A method for making a strain sensor is provided. The method includes growing an iron (Fe) thin seed layer with patterns on a top surface of a silicon oxide isolation layer formed on a top surface of a silicon wafer; synthesizing a plurality of vertically aligned carbon nanotubes (VACNTs) on top surfaces of the iron (Fe) thin seed layer to form electrodes of the strain sensor;

forming a first polydimethylsiloxane (PDMS) layer disposed on and between adjacent VACNTs of the plurality of VACNTs; peeling the first PDMS layer and the plurality of VACNTs embedded in the first PDMS layer off from the top surface of the silicon oxide isolation layer; and forming a second PDMS layer on a bottom surface of the plurality of VACNTs embedded in the first PDMS layer.

### CROSS-REFERENCE TO RELATED APPLICATION

This application claims the benefit of U.S. Provisional Application Ser. No. 63/257,128, filed Oct. 19, 2021, which is hereby incorporated by reference in its entirety including any tables, figures, or drawings.

### BACKGROUND OF THE INVENTION

The rapid development of the wearable electronics has attracted great interests in recent years for various potential applications including human motion detection, soft robotics, electronic skin, and human-machine interfaces. Stretchable and flexible strain sensor can transduce mechanical deformations into electric signals, making it possible to detect strains induced by human activities. To meet the requirements of these potential applications, it is desirable to develop strain sensors with quick response, low hysteresis, fast response, high stretchability, and robust long-term reliability.

Furthermore, it is also desirable to integrate strain sensors that are transparent without obscuring light transmission with multi-sensing components that require a clear light path.

Different types of materials can be used for fabrication of flexible substrate and stretchable electrodes of the strain sensors. For instance, polydimethylsiloxane (PDMS) with soft, deformation and great light transmittance properties can be used for making the flexible substrate. Further, ecoflex and hydrogel having excellent stretchability can also be used for making large stretchable strain sensors (ϵ>100%). In addition, stretchable material including stretchable elastomer such as epoxy aliphatic acrylate and aliphatic urethane diacrylate, polyvinylidene fluoride (PVDF), thermoplastic polyurethane (TPU), silicone rubber, styrene-(ethylene-butylene)-styrene (SEBS), polyimide, can be utilized for making the stretchable substrate as well. For fabrication of the electrodes, a carbon material such as carbon black, graphene nanoplates, carbon nanotubes, and graphene is preferable due to its good conductivity, low cost and simple fabrication process. For making conductive electrodes, silver nanoparticles, liquid metal, Au, Cu wires have been investigated.

Based on different sensing mechanisms, strain sensors can be divided into several categories including optical, capacitive, piezoelectric and resistive strain sensors. Optical strain sensors rely on light transmittance change of the sensing material under different strain conditions for strain measurements, thereby requiring integration with additional light intensity detection components. Piezoelectric strain sensors generate signals resulting from normal force between two electrodes under bending or stretching deformation. As a result, its applications for large measurement range are limited. Resistive strain sensors are also commonly used thanks to its simple structure and fabrication process. However, resistance change of the sensor can be generated not only from the geometric structure changing but also from the conductivity of the material under applied changing strain, leading to poor linearity and large hysteresis behaviors. By contrast, capacitance change of the capacitive strain sensor mainly relies on the geometry change of the dielectric material and the sensing electrode, thereby having good linearity and low hysteresis.

### BRIEF SUMMARY OF THE INVENTION

There continues to be a need in the art for improved designs and techniques for a method for making strain sensors.

According to a first embodiment of the subject invention, a method of for making a strain sensor is provided. The method comprises growing an iron (Fe) thin seed layer with patterns on a top surface of a silicon oxide isolation layer formed on a top surface of a silicon wafer; synthesizing a plurality of vertically aligned carbon nanotubes (VACNTs) on top surfaces of the iron (Fe) thin seed layer to form electrodes of the strain sensor; forming a first polydimethylsiloxane (PDMS) layer disposed on and between adjacent VACNTs of the plurality of VACNTs; peeling the first PDMS layer and the plurality of VACNTs embedded in the first PDMS layer off from the top surface of the silicon oxide isolation layer; and forming a second PDMS layer on a bottom surface of the plurality of VACNTs embedded in the first PDMS layer. Moreover, the iron (Fe) thin seed layer has a thickness of about 2 nm and the silicon wafer has a thickness of about 1 μm. The synthesizing a plurality of VACNTs is performed by a microwave plasma enhanced chemical vapor deposition (PECVD) method. The forming a first polydimethylsiloxane (PDMS) layer is performed by spinning a first degassed PDMS precursor mixer on top and lateral surfaces of the VACNTs to cover the top and lateral surfaces of the

VACNTs. Furthermore, the PDMS precursor mixer has a ratio of monomer and curing agent in a range of about 10:1. The spinning is performed by a spin coater at a rotation speed of about 150 rotations/minute for about 40 seconds. The forming the second PDMS layer is performed by coating a second degassed PDMS precursor mixer at a rotation speed of about 2000 rotations/minute for about 40 seconds and being cured for two hours at a temperature of about 70° C.

In a second embodiment of the subject invention, another method for making a strain sensor is provided. The method comprises growing an iron (Fe) thin seed layer on a top surface of a silicon oxide isolation layer formed on a top surface of a silicon wafer; synthesizing a plurality of vertically aligned carbon nanotubes (VACNTs) on top surfaces of the iron (Fe) thin seed layer to form electrodes of the strain sensor; forming a first polydimethylsiloxane (PDMS) layer disposed on and between adjacent VACNTs of the plurality of VACNTs; peeling the first PDMS layer and the plurality of VACNTs embedded in the first PDMS layer off from the top surface of the silicon oxide isolation layer; turning the peeled-off first PDMS layer with the plurality of VACNTs upside down; attaching the silicon wafer to a bottom surface of the peeled-off first PDMS layer with the plurality of VACNTs; covering contact areas of the VACNTs with protection tapes; forming a second PDMS layer on a top surface of the plurality of VACNTs embedded in the first PDMS layer; and removing the protection tapes from the silicon wafer. Moreover, the iron (Fe) thin seed layer has a thickness of about 2 nm and the silicon wafer has a thickness of about 1 μm. The synthesizing a plurality of VACNTs is performed by a microwave plasma enhanced chemical vapor deposition (PECVD) method. The forming a first PDMS layer is performed by spinning a first degassed PDMS precursor mixer on top and lateral surfaces of the VACNTs to cover the top and lateral surfaces of the VACNTs. Furthermore, the first PDMS precursor mixer has a ratio of monomer and curing agent in a range of about 10:1. The spinning is performed by a spin coater at a rotation speed of about 150 rotations/minute for about 40 seconds. The forming the second PDMS layer is performed by coating a second degassed PDMS precursor mixer at a rotation speed of about 2000 rotations/minute for about 40 seconds and being cured for about two hours at a temperature of about 70° C.

In some embodiment of the subject invention, a strain sensor comprises a flexible substrate made of polydimethylsiloxane (PDMS); and a plurality of vertically aligned carbon nanotubes (VACNTs) embedded in the flexible substrate. The flexible substrate and the plurality of VACNTs are made according to the first embodiment of the method for making a strain sensor.

In certain embodiment of the subject invention, a strain sensor comprises a flexible substrate made of polydimethylsiloxane (PDMS) and a plurality of vertically aligned carbon nanotubes (VACNTs) embedded in the flexible substrate. The flexible substrate and the plurality of VACNTs are made according to the second embodiment of the method for making a strain sensor.

### BRIEF DESCRIPTION OF THE DRAWINGS

FIG. 1 shows a flow chart of a process for fabricating the flexible transparent strain sensor with the 3D electrodes, according to an embodiment of the subject invention.

FIGS. 2A-2H are schematic representations of steps of the fabrication process of the flexible transparent strain sensor with the 3D electrodes based on vertically aligned carbon nanotubes, according to an embodiment of the subject invention.

### DETAILED DISCLOSURE OF THE INVENTION The embodiments of subject invention pertain to a method and systems for making vertically aligned carbon nanotube based strain sensors.

The terminology used herein is for the purpose of describing particular embodiments only and is not intended to be limiting of the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one having ordinary skill in the art to which this invention pertains. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

When the term “about” is used herein, in conjunction with a numerical value, it is understood that the value can be in a range of 90% of the value to 110% of the value, i.e. the value can be +/−10% of the stated value. For example, “about 1 kg” means from 0.90 kg to 1.1 kg.

In describing the invention, it will be understood that a number of techniques and steps are disclosed. Each of these has individual benefits and each can also be used in conjunction with one or more, or in some cases all, of the other disclosed techniques. Accordingly, for the sake of clarity, this description will refrain from repeating every possible combination of the individual steps in an unnecessary fashion. Nevertheless, the specification and claims should be read with the understanding that such combinations are entirely within the scope of the invention and the claims.

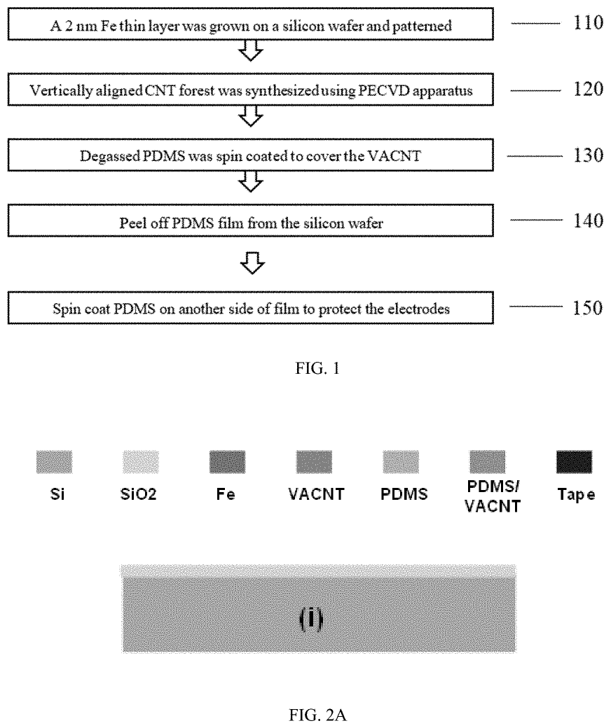

Referring to FIG. 1, a flow chart of the fabrication process of the flexible capacitance strain sensor is shown. First, in step 110, an iron (Fe) thin seed layer having a thickness, for example about 2 nm, is grown on a silicon wafer with a silicon oxide isolation layer having a thickness, for example 1 μm, on a top surface of a silicon wafer.

Then, in step 120, the vertically aligned carbon nanotubes (VACNT) arrays are synthesized by a microwave plasma enhanced chemical vapor deposition (PECVD) method to form the sensor electrodes.

Next, in step 130, a degassed PDMS precursor mixer having for example, a ratio of monomer/curing agent in a range of about 10/1 is spun on the surface of the wafer to cover the VACNT by a spin coater with a rotation speed of for example, about 150 rotations/minute for about 40 seconds. Then, in step 140, the PDMS is used to peel off the VACNT electrodes from the silicon wafer.

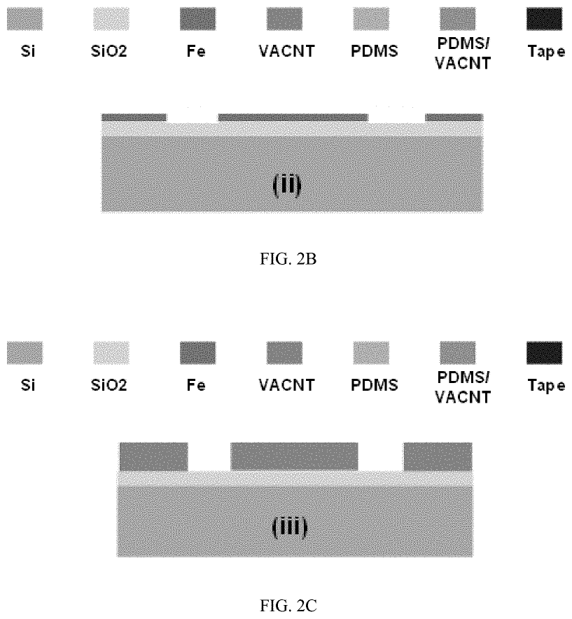

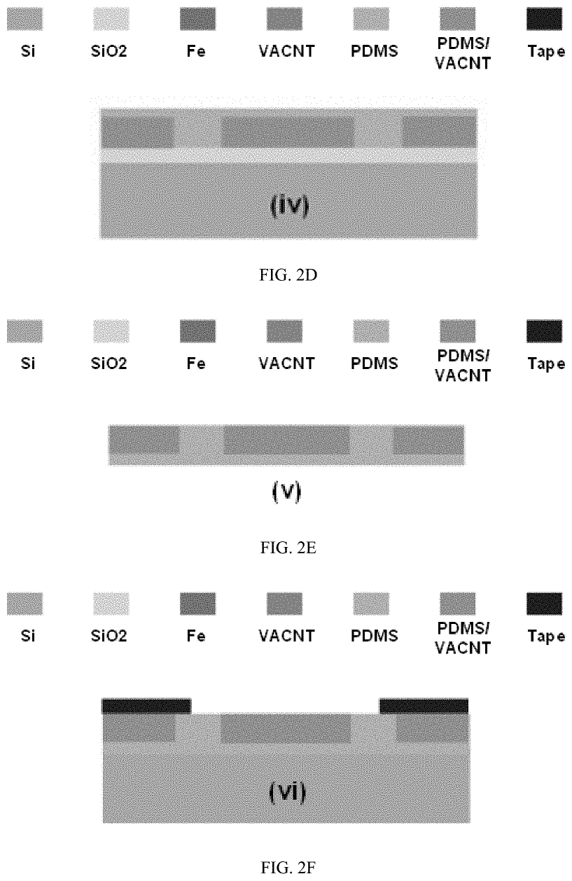

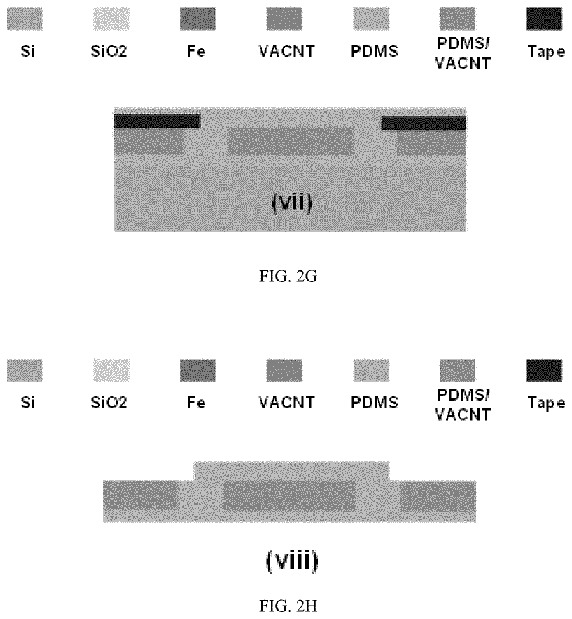

Next, in step 150, an additional layer of PDMS is coated with a rotation speed of, for example, about 2000 rotations/minutes for about 40 seconds and cured for about two hours on a hot plate at a temperature of about 70° C. to protect another side of the CNT electrodes. Referring to FIGS. 2A-2H, the steps of the fabrication process of the flexible transparent strain sensor with the 3D electrodes based on vertically aligned carbon nanotubes are illustrated with more details.

First, a silicon oxide isolation layer having a thickness of, for example, about 1 μm, is formed on a top surface of a silicon wafer as shown in FIG. 2A. Then, an iron (Fe) thin seed layer having a thickness of, for example, about 2 nm, is grown on a top surface of the silicon oxide isolation layer formed and an E-beam evaporator is used to form patterns on the iron (Fe) thin seed layer for interdigital finger shape with lift-off process as shown in FIG. 2B.

Next, the VACNT arrays are synthesized by a microwave plasma enhanced chemical vapor deposition (PECVD) method to form the sensor electrodes on the silicon wafer as shown in FIG. 2C.

Then, a degassed PDMS precursor mixer having a ratio of monomer/curing agent, for example, about 10:1, is spun on the top surface of the wafer to cover the VACNT by a spin coater with a rotation speed of, for example, about 150 rotations/minute for about 40 seconds as shown in FIG. 2D.

Next, to reduce the gas bubbles in the PDMS substrate and to enhance the PDMS filling performance into the intervals of the carbon nanotubes, the silicon wafer is put into a vacuum chamber to be vacuumed for, for example, about 20 minutes. Then, the PDMS is cured on a hot plate for about two hours at a temperature of about 70° C.

The thickness of the PDMS is characterized to be, for example, about 400 μm and the PDMS is used to peel off the VACNT electrodes from the silicon wafer. The PDMS may be purchased from Dowsil.

As shown in FIG. 2E, the PDMS with the 3D electrodes formed is peeled off from the silicon wafer.

Then, the PDMS flexible substrate with the 3D electrodes is turned upside down and the peeled off silicon wafer is attached to the opposite side of the flexible substrate, followed by protecting the contact area with tapes as shown in FIG. 2F.

To protect another side of the CNT electrodes, an additional PDMS layer is coated onto the flexible substrate with a rotation speed of, for example, about 2000 rotations/minutes for about 40 seconds as shown in FIG. 2G and cured for about two hours on a hot plate at a temperature of about 70° C.

Then, the tapes are removed and the flexible strain sensor is peeled off from the silicon wafer as shown in FIG. 2H.

The capacitive strain sensor obtained by the above fabrication method is designed to have interdigital electrodes with flexible PDMS substrate to improve sensitivity, transparency, linearity and to reduce the hysteresis. Moreover, compared with the traditional capacitive strain sensor with parallel electrodes, the interdigital electrodes of the subject invention can reduce the thickness of the sensor. Additionally, the flexible sensor exhibits excellent dynamic response such as fast response, stability, and robustness, making it possible for the strain sensor to be utilized in a wearable device to monitor various human activities such as large-scale motions including finger bending, knee bending, neck bending, wrist bending, and elbow bending, and tiny-scale motions such as speaking and recognize the robot movements in real time. As a result, a patient with throat and vocalization problems can send an alarm signal to the doctors by opening mouth. In another example, disabled persons suffering deafness can be trained with the strain sensors for pronunciation exercises.

Thus, the flexible capacitive sensor structure with three dimensional (3D) interdigital electrodes fabricated via vertically aligned carbon nanotubes (VACNT) is ideal for the development of highly stable, low hysteresis, transparent and pressure-insensitive strain sensors. Compared with the conventional sandwich structure with thick dielectric material, parallel interdigital electrodes of the subject invention can greatly reduce the thickness of the whole device. Moreover, the strain sensor fabricated by the methods of the embodiments of the subject invention has an ultralow hysteresis, excellent pressure insensitive performance, fast response, good long-term stability and durability.

The enhanced flexible strain sensor has been successfully demonstrated as a wearable device for precise monitoring different types of human body activities including finger, knee, elbow, wrist, and neck with large strain signals. Thanks to the enhanced performance, the flexible strain sensor can be applied to a wide range of fields including human motion detection, soft robotics, and medical care.

All patents, patent applications, provisional applications, and publications referred to or cited herein are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application and the scope of the appended claims. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

We claim:

1. A method for making a strain sensor, the method comprising:
growing an iron (Fe) thin seed layer with patterns on a top surface of a silicon oxide isolation layer formed on a top surface of a silicon wafer;
synthesizing a plurality of vertically aligned carbon nanotubes (VACNTs) on top surfaces of the iron (Fe) thin seed layer to form electrodes of the strain sensor;
forming a first polydimethylsiloxane (PDMS) layer disposed on and between adjacent VACNTs of the plurality of VACNTs;
peeling the first PDMS layer and the plurality of VACNTs embedded in the first PDMS layer off from the top surface of the silicon oxide isolation layer; and
forming a second PDMS layer on a bottom surface of the plurality of VACNTs embedded in the first PDMS layer.

2. The method of claim 1, wherein the iron (Fe) thin seed layer has a thickness of about 2 nm and the silicon wafer has a thickness of about 1 μm.

3. The method of claim 1, wherein the synthesizing a plurality of VACNTs is performed by a microwave plasma enhanced chemical vapor deposition (PECVD) method.

4. The method of claim 1, wherein the forming a first polydimethylsiloxane (PDMS) layer is performed by spinning a first degassed PDMS precursor mixer on top and lateral surfaces of the VACNTs to cover the top and lateral surfaces of the VACNTs.

5. The method of claim 4, wherein the PDMS precursor mixer has a ratio of monomer to curing agent in a range of about 10:1.

6. The method of claim 4, wherein the spinning is performed by a spin coater at a rotation speed of about 150 rotations/minute for about 40 seconds.

7. The method of claim 1, wherein the forming the second PDMS layer is performed by coating a second degassed PDMS precursor mixer at a rotation speed of about 2000 rotations/minute for about 40 seconds and curing for about two hours at a temperature of about 70° C.

8. A method for making a strain sensor, the method comprising:
growing an iron (Fe) thin seed layer on a top surface of a silicon oxide isolation layer formed on a top surface of a silicon wafer;
synthesizing a plurality of vertically aligned carbon nanotubes (VACNTs) on top surfaces of the iron (Fe) thin seed layer to form electrodes of the strain sensor;
forming a first polydimethylsiloxane (PDMS) layer disposed on and between adjacent VACNTs of the plurality of VACNTs;
peeling the first PDMS layer and the plurality of VACNTs embedded in the first PDMS layer off from the top surface of the silicon oxide isolation layer;
turning the peeled-off first PDMS layer with the plurality of VACNTs upside down;
attaching the silicon wafer to a bottom surface of the peeled-off first PDMS layer with the plurality of VACNTs;
covering contact areas of the VACNTs with protection tape;
forming a second PDMS layer on a top surface of the plurality of VACNTs embedded in the first PDMS layer; and
removing the protection tape from the silicon wafer.

9. The method of claim 8, wherein the iron (Fe) thin seed layer has a thickness of about 2 nm and the silicon wafer has a thickness of about 1 μm.

10. The method of claim 8, wherein the synthesizing a plurality of VACNTs is performed by a microwave plasma enhanced chemical vapor deposition (PECVD) method.

11. The method of claim 8, wherein the forming a first PDMS layer is performed by spinning a first degassed PDMS precursor mixer on top and lateral surfaces of the VACNTs to cover the top and lateral surfaces of the VACNTs.

12. The method of claim 11, wherein the first PDMS precursor mixer has a ratio of monomer to curing agent in a range of about 10:1.

13. The method of claim 11, wherein the spinning is performed by a spin coater at a rotation speed of about 150 rotations/minute for about 40 seconds.

14. The method of claim 8, wherein the forming the second PDMS layer is performed by coating a second degassed PDMS precursor mixer at a rotation speed of about 2000 rotations/minute for about 40 seconds and curing for about two hours at a temperature of about 70° C.

15. A strain sensor comprising:
a flexible substrate made of polydimethylsiloxane (PDMS); and
a plurality of vertically aligned carbon nanotubes (VACNTs) embedded in the flexible substrate,
wherein the flexible substrate and the plurality of VACNTs are made according to the method of claim 1.

16. A strain sensor comprising:
a flexible substrate made of polydimethylsiloxane (PDMS); and
a plurality of vertically aligned carbon nanotubes (VACNTs) embedded in the flexible substrate,
wherein the flexible substrate and the plurality of VACNTs are made according to the method of claim 8.
